(19) United States
(12) Patent Application Publication
(10) Pub. No.: US 2013/0092981 A1
(43) Pub. Date: Apr. 18, 2013

(54) SIGE HBT HAVING A POSITION CONTROLLED EMITTER-BASE JUNCTION

(71) Applicants: Feng Han, Shanghai (CN); Donghua Liu, Shanghai (CN); Jun Hu, Shanghai (CN); Wenting Duan, Shanghai (CN); Jing Shi, Shanghai (CN)

(72) Inventors: Feng Han, Shanghai (CN); Donghua Liu, Shanghai (CN); Jun Hu, Shanghai (CN); Wenting Duan, Shanghai (CN); Jing Shi, Shanghai (CN)

(73) Assignee: SHANGHAI HUA HONG NEC ELECTRONICS CO., LTD., Shanghai (CN)

(21) Appl. No.: 13/613,151

(22) Filed: Sep. 13, 2012

(30) Foreign Application Priority Data
Oct. 13, 2011 (CN) 201110310522.8

(51) Int. Cl. H01L 29/737

(52) U.S. Cl. 257/197; 257/E29.188

(57) ABSTRACT

A SiGe HBT having a position controlled emitter-base junction is disclosed. The SiGe HBT includes: a collector region formed of an N-doped active region; a base region formed on the collector region and including a base epitaxial layer, the base epitaxial layer including a SiGe layer and a capping layer formed thereon, the SiGe layer being formed of a SiGe epitaxial layer doped with a P-type impurity, the capping layer being doped with an N-type impurity; and an emitter region formed on the base region, the emitter region being formed of polysilicon. By optimizing the distribution of impurities doped in the base region, a controllable position of the emitter-base junction and adjustability of the reverse withstanding voltage thereof can be achieved, and thereby increasing the stability of the process and improving the uniformity within wafer.

### CROSS-REFERENCE TO RELATED APPLICATIONS

This application claims the priority of Chinese patent application number 201110310522.8, filed on Oct. 13, 2011, the entire contents of which are incorporated herein by reference.

### TECHNICAL FIELD

The present invention relates to the field of integrated circuits manufacturing, and more particularly, to a SiGe HBT having a position controlled emitter-base (EB) junction.

### BACKGROUND

In Radio Frequency (RF) applications, higher and higher characteristic frequencies of the device are being required. Although RFCMOSs (Radio-Frequency Complementary Metal-Oxide Semiconductors) can realize higher characteristic frequencies in advanced technologies, they can hardly reach characteristic frequencies higher than 40 GHz and always lead to high costs in development of advanced technologies. For this reason, devices such as RFCMOSs made in advanced technologies are not able to completely meet the RF requirements. Although devices made by using compound semiconductors can realize extremely high characteristic frequencies, they have disadvantages of high cost of materials and small sizes. Besides, most of the compound semiconductors are toxic. Therefore, their applications are limited. In contrary, SiGe (Silicon-Germanium) HBTs (Heterojunction Bipolar Transistors) are good choices for, as well as the mainstream of, ultra-high-frequency devices for the following reasons. Firstly, they take advantage of the difference between energy bands of strained SiGe and strained Si to generate a strain effect, which can alter properties of materials, thereby improving carriers injection efficiency of emitter-region and thus increasing the current magnification of the device. Secondly, a lower base resistance and a higher characteristic frequency can be achieved through a heavily doped SiGe base region. Thirdly, the SiGe process is basically compatible with the silicon process.

Thus it can be seen from the above description that existing SiGe HBTs have been used as an effective and easy-to-be-used means to simultaneously achieve a higher characteristic frequency, an increased doping concentration of the base region, and a reduced thickness of the base region. However, existing SiGe HBTs still have problems as follows: on one hand, improvement of doping concentrations of the base region will reduce the reverse withstanding voltage of an emitter-base junction; on the other hand, reduction of the base region thickness will increase the difficulty in precisely controlling the formation position of the emitter-base junction, and will reduce the tolerance to the instability of the process. In conventional methods of forming an appropriate emitter-base junction of a transistor, an annealing process with strict conditions on annealing temperature and duration time, as well as doping concentration of polysilicon is employed to make sure that the emitter-base junction is formed at a germanium containing region of the base epitaxial layer. In such methods, the annealing temperature and duration time in the last step must be well controlled so as to make the N-type impurity in the polysilicon emitter region diffuse into the base epitaxial layer. For example, in the prior art of forming a SiGe HBT, before a thermal annealing process is applied to the base and emitter regions, the concentration distribution of the N-type impurity, such as arsenic (As) in the polysilicon emitter region remains unchanged, as shown in FIG. 1A, and after the thermal annealing process for the base and emitter regions of the SiGe HBT is performed, the N-type impurity arsenic in the polysilicon emitter region diffuses into the base epitaxial layer, and thereafter an emitter-base junction is formed in the base region of the SiGe HBT, as shown in FIG. 1B. In the above process, failures in appropriate control of the annealing temperature and duration time will result in insufficient diffusion of the N-type impurity arsenic from the polysilicon emitter region into the base epitaxial layer, which will lead to an insufficient current gain, or result in excessive diffusion of the N-type impurity arsenic from the polysilicon emitter region into the base epitaxial layer, which will lead to an excessive current gain and hence a low BVceo (the reverse breakdown voltage between collector and emitter), so that the stability of the process cannot be controlled and the transistor may be broken down due to incorrect uses.

Therefore, a new structure is needed, with which the formation of an emitter-base junction of a transistor can be located at a predetermined position, and the reverse withstanding voltage thereof can be adjusted.

### SUMMARY OF THE INVENTION

An objective of the present invention is to provide a SiGe HBT having a position controlled emitter-base junction to overcome the shortcomings of the prior art.

To achieve the above objective, the present invention provides a SiGe HBT having a position controlled emitter-base junction, which includes:

a collector region formed of an N-doped active region;

a base region formed on the collector region and including a base epitaxial layer, the base epitaxial layer including a SiGe layer and a capping layer formed thereon, the SiGe layer being formed of a SiGe epitaxial layer doped with a P-type impurity, the capping layer being doped with an N-type impurity; and

an emitter region formed on the base region, the emitter region being formed of polysilicon.

Preferably, the base epitaxial layer further includes a buffer layer formed under the SiGe layer.

Preferably, the buffer layer is undoped.

Preferably, the SiGe epitaxial layer is further doped with germanium, the concentrations of the germanium and the P-type impurity being determined according to a target performance of the SiGe HBT.

Preferably, a position and a reverse withstanding voltage of the emitter-base junction are determined by a concentration and a position of the N-type impurity doped in the capping layer as well as a concentration of the P-type impurity doped in the SiGe layer.

Preferably, the N-type impurity doped in the capping layer is phosphorus or arsenic.

Preferably, the P-type impurity doped in the SiGe layer is boron.

Compared with the prior art, the present invention adopts such a SiGe HBT structure that the base region of the SiGe HBT is formed by a base epitaxial layer; the base epitaxial layer includes a SiGe layer and a capping layer formed thereon; and the doping type of the capping layer is changed from P-type to N-type. By accurately controlling the position and concentration of the N-type impurity doped in the capping layer during the epitaxial growth process, and co-working with the doping of boron in the SiGe layer, the distribution of impurities in the base region is optimized, and therefore the reverse withstanding voltage of the emitter-base junction is not reduced even when the doping concentration of the base region is improved, and the formation of the emitter-base junction can also be located at a predetermined position even when the thickness of the base region is reduced, so that the formation position of the emitter-base junction of a transistor can be controlled and the reverse withstanding voltage thereof can also be adjusted.

### BRIEF DESCRIPTION OF THE DRAWINGS

The present invention will be further described and specified by using figures and implementation details as follows:

FIG. 1A is a schematic view showing the distribution of doped impurities before a thermal annealing process is applied to the base and emitter regions of a SiGe HBT according to the prior art.

FIG. 1B is a schematic view showing the distribution of doped impurities after a thermal annealing process is applied to the base and emitter regions of a SiGe HBT according to the prior art.

FIG. 2 is a schematic view showing the SiGe HBT having a position controlled emitter-base junction according to the present invention.

FIG. 3 is a schematic view showing the structure of the base epitaxial layer in the SiGe HBT having a position controlled emitter-base junction according to the present invention.

FIG. 4A is a schematic view showing the distribution of doped impurities before a thermal annealing process is applied to the base epitaxial layer and the emitter region of the SiGe HBT having a position controlled emitter-base junction according to the present invention.

FIG. 4B is a schematic view showing the distribution of doped impurities after a thermal annealing process is applied to the base epitaxial layer and the emitter regions of the SiGe HBT having a position controlled emitter-base junction according to the present invention.

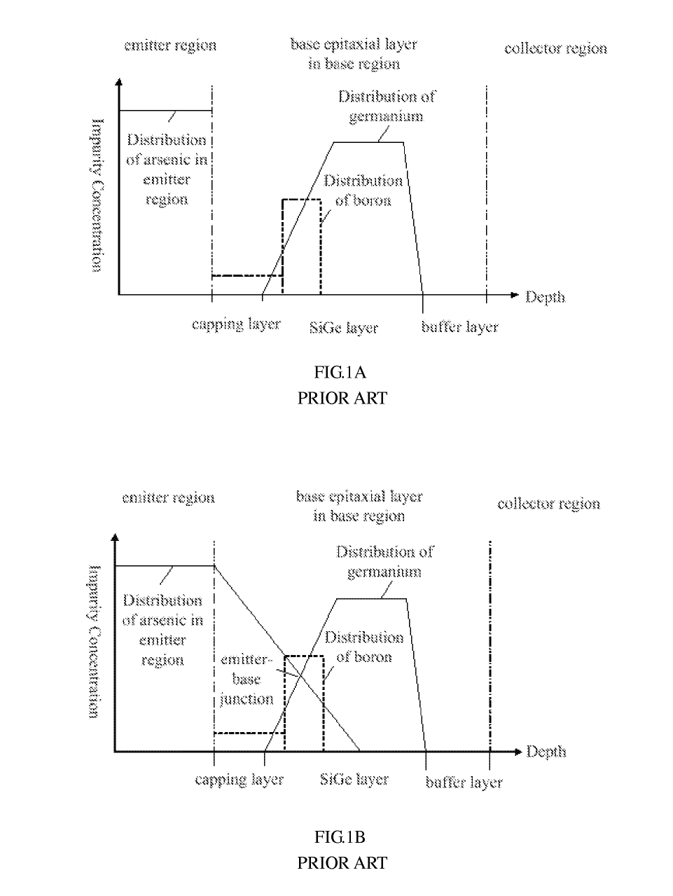

### DETAILED DESCRIPTION

In order to easily understand advantages and beneficial effects of this invention from contents of this specification, the embodiments of the present invention will be described and specified by using specific examples and figures in follows. The present invention can also be implemented or applied in other specific examples, and details of this specification based on other views and applications can be made to various modifications and variations without departing from the spirit or scope of the invention.

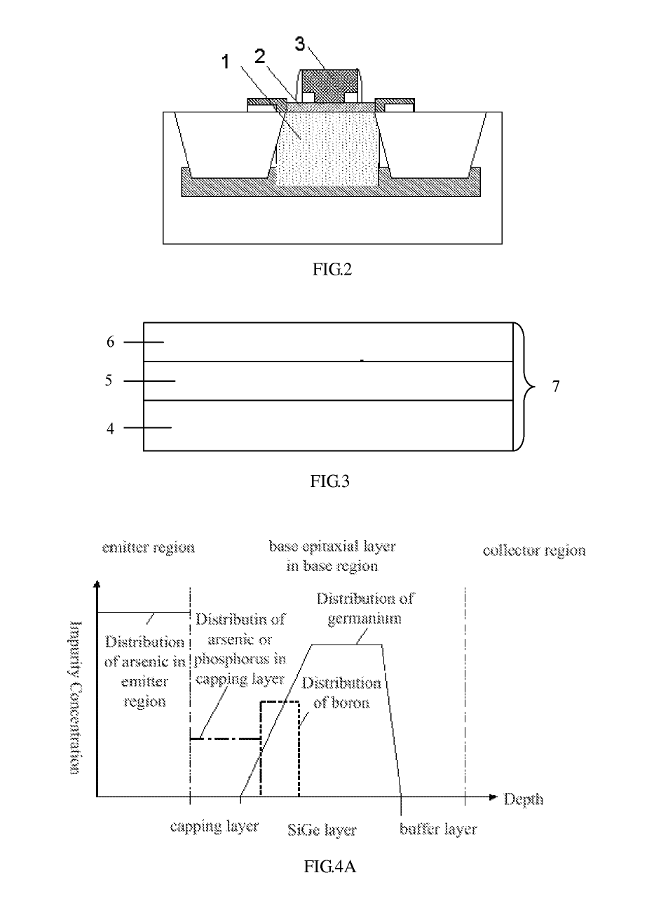

FIG. 2 is a schematic view showing the SiGe HBT having a position controlled emitter-base junction according to the present invention. As shown in FIG. 2, the SiGe HBT having a position controlled emitter-base junction of the present invention includes a collector region 1; a base region 2 is formed on the collector region 1 and an emitter region 3 is formed on the base region 2. The collector region 1 is formed of an N-doped active area. As shown in FIG. 3, the base region 2 includes a base epitaxial layer 7, and the base epitaxial layer 7 includes a SiGe layer 5 and a capping layer 6 covering the SiGe layer 5. The SiGe layer 5 is formed on the collector region 1 by germanium-silicon epitaxial growth. During the germanium-silicon epitaxial growth process, in addition to germanium, a P-type impurity, which is boron herein, is also doped. The concentrations of the germanium and the P-type impurity doped in the SiGe layer 5 are determined according to a target performance of the SiGe HBT. The capping layer 6 is formed on the SiGe layer 5 by epitaxial growth. During the epitaxial growth process, an N-type impurity, which is phosphorus or arsenic herein, is doped. The concentration and position of the N-type impurity doped in the capping layer 6 and the concentration of the P-type impurity doped in the SiGe layer 5, together determine a position of the emitter-base junction and a reverse withstanding voltage of the emitter-base junction. The base epitaxial layer 7 may further include a buffer layer 4, as shown in FIG. 3. The buffer layer 4 is formed on the collector region 1 by epitaxial growth, and the SiGe layer 5 is formed on the buffer layer 4. The buffer layer 4 is not dope with any impurity. The emitter region 3 is formed of polysilicon.

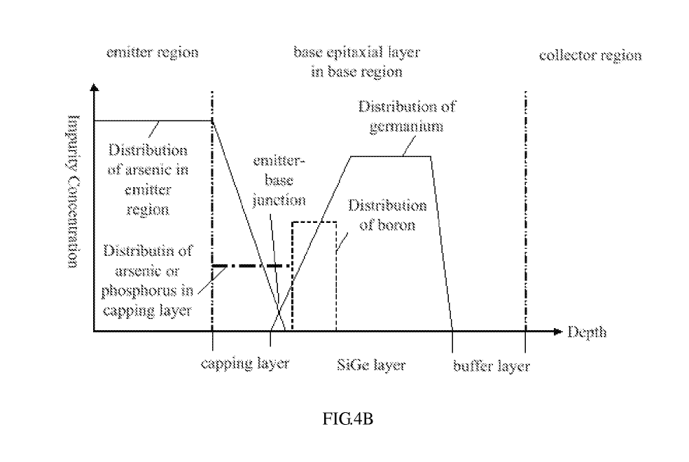

Thereafter, an N-type impurity is doped or implanted into the polysilicon, after which, the distribution of doped impurities is as shown in FIG. 4A. After a thermal annealing process is performed, the doped N-type impurity will be evenly distributed in the polysilicon emitter region, and will also diffuse into the capping layer 6 of the base epitaxial layer 7. Since the capping layer 6 is doped with an N-type impurity (i.e. phosphorus or arsenic) instead of a P-type impurity, after the distribution of N-type impurity from the polysilicon into the capping layer 6, the polysilicon emitter region will be well connected with the capping layer 6, and the distribution of doped impurities is as shown in FIG. 4B. Then, the position of the emitter-base junction and the reverse withstanding voltage of the emitter-base junction are determined by the position and the concentration of the N-type impurity doped in the capping layer 6 as well as the concentration of the P-type impurity doped in the SiGe layer 5, and therefore no thermal annealing process is needed to control the formation of the emitter-base junction. Accordingly, the annealing temperature or the annealing duration time can be reduced, and the overall duration time of the thermal processes originally needed to control the formation position of the emitter-base junction in the prior art can be reduced, so that the process window and the stability of the process can be increased, and the uniformity within wafer can also be improved.

Compared with the prior art, the present invention adopts such a SiGe HBT structure that the base region of the SiGe HBT is formed by a base epitaxial layer; the base epitaxial layer includes a SiGe layer and a capping layer formed thereon; and the doping type of the capping layer is changed from P-type to N-type. By accurately controlling the position and concentration of the N-type impurity doped in the capping layer during the epitaxial growth process, and co-working with the doping of boron in the SiGe layer, the distribution of impurities in the base region is optimized, and therefore the reverse withstanding voltage of the emitter-base junction is not reduced even when the doping concentration of the base region is improved, and the formation of the emitter-base junction can also be located at a predetermined position even when the thickness of the base region is reduced, so that the formation position of the transistor emitter-base junction can be controlled and the reverse withstanding voltage thereof can also be adjusted.

The above embodiments are provided as examples for the purpose of describing the principle and effects of the invention and are not intended to limit the scope of the invention in any way. It will be apparent to those skilled in the art that various modifications and variations can be made without departing from the spirit or scope of the invention. Thus, it is intended that the present invention covers the modifications and variations of this invention provided they fall within the scope of the following claims and their equivalents.

What is claimed is:

1. A SiGe HBT having a position controlled emitter-base junction, comprising:
a collector region formed of an N-doped active region;
a base region formed on the collector region and comprising a base epitaxial layer, the base epitaxial layer comprising a SiGe layer and a capping layer formed thereon, the SiGe layer being formed of a SiGe epitaxial layer doped with a P-type impurity, the capping layer being doped with an N-type impurity; and
an emitter region formed on the base region, the emitter region being formed of polysilicon.

2. The SiGe HBT having a position controlled emitter-base junction according to claim 1, wherein the base epitaxial layer further comprises a buffer layer formed under the SiGe layer.

3. The SiGe HBT having a position controlled emitter-base junction according to claim 2, wherein the buffer layer is undoped.

4. The SiGe HBT having a position controlled emitter-base junction according to claim 2, wherein the SiGe epitaxial layer is further doped with germanium, the concentrations of the germanium and the P-type impurity being determined according to a target performance of the SiGe HBT.

5. The SiGe HBT having a position controlled emitter-base junction according to claim 2, wherein a position and a reverse withstanding voltage of the emitter-base junction are determined by a concentration and a position of the N-type impurity doped in the capping layer as well as a concentration of the P-type impurity doped in the SiGe layer.

6. The SiGe HBT having a position controlled emitter-base junction according to claim 2, wherein the N-type impurity doped in the capping layer is phosphorus or arsenic.

7. The SiGe HBT having a position controlled emitter-base junction according to claim 2, wherein the P-type impurity doped in the SiGe layer is boron.
